(19) United States
(12) Patent Application Publication
(10) Pub. No.: US 2026/0110407 A1
(43) Pub. Date: Apr. 23, 2026

(54) WATERPROOF LIGHT-EMITTING DIODE PLUG-IN LIGHT AND METHOD OF MAKING THEREOF

(71) Applicant: DONGGUAN YONGFENG LIGHTING CO., LTD, Dongguan City (CN)

(72) Inventor: ZHUMEI DENG, Dongguan (CN)

(21) Appl. No.: 18/923,600

(22) Filed: Oct. 22, 2024

(51) Int. Cl. F21K 9/90; F21K 9/66; F21S 4/10; F21V 19/00; F21V 31/00; F21V 31/04; F21Y 115/10; H10H 20/85

(52) U.S. Cl. CPC F21K 9/90; F21K 9/66; F21S 4/10; F21V 19/0025; F21V 31/005; F21V 31/04; F21Y 2115/10; H10H 20/8502

(57) ABSTRACT

A method of making a Surface Mount Device (SMD) light-emitting diode (LED) plug-in light string is disclosed. The method includes: connecting positive and negative poles of an SMD to a first and a second metal conductors, respectively; encapsulating at least a top portion of the SMD with a colloid; connecting the first and second metal conductors to first and second wires, respectively; inserting a rear plug in a space between the first and second wires to form a partially-finished assembly; and waterproofing the partially-finished assembly.

### FIELD

This relates to light strings, and more particularly, to a Surface Mount Device (SMD) light-emitting diode (LED) plug-in light string with certain waterproof properties.

### BACKGROUND

Traditional LED light strings with waterproof properties are difficult and expensive to manufacture on a large scale and have relatively short service lifespans.

### SUMMARY

In one aspect, this disclosure relates to a SMD LED plug-in light string with certain waterproof properties. In another aspect, the disclosure relates to a method of making such SMD LED plug-in light string with certain waterproof properties.

### BRIEF DESCRIPTION OF THE DRAWINGS

FIGS. 1A, 1B, 2, 3A, 3B, 4A, 4B, 5A, 5B, 6A, 6B, 7A, 7B, 8A, 8B, 8C, 9A, 9B, 10A, 10B, and 11 illustrate the exemplary steps in manufacturing SMD LED plug-in light string with certain waterproof properties, according to an embodiment of the disclosure.

FIGS. 12A and 12B illustrate an exemplary SMD LED that can be used in the making of a plug-in light string, according to an embodiment of the disclosure.

### DETAILED DESCRIPTION

Embodiments of the present disclosure will be described below in conjunction with the accompanying drawings, but it should be appreciated by those skilled in the art that the embodiments described below are exemplary, rather than exhaustive. They are only used to illustrate the present disclosure and should not be regarded as limiting the scope of the present disclosure. All other embodiments obtained by those of ordinary skill in the art without creative efforts based on the embodiments disclosed herein shall fall within the scope of the present disclosure.

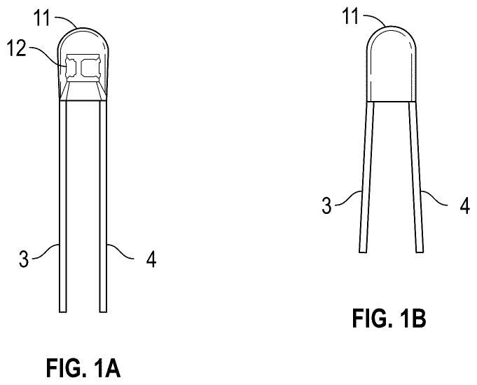

FIGS. 1A, 1B, 2, 3A, 3B, 4A, 4B, 5A, 5B, 6A, 6B, 7A, 7B, 8A, 8B, 8C, 9A, 9B, 10A, 10B, and 11 illustrate the exemplary steps in the making of a SMD LED light string, according to an embodiment of the disclosure. As shown in FIG. 1a, the positive and negative poles of a SMD 12 are respectively welded on two metal conductors 3, 4. FIGS. 12A and 12B illustrate the positive pole 23 and negative pole 24 of an exemplary SMD 22 such as the one used in the step of FIG. 1. Although FIG. 1a shows that the positive and negative poles of the SMD 12 are welded to the end of the metal conductors 3, 4, respectively, it should be understood that the SMD 12 can be welded to any other parts of the metal conductors 3, 4. The SMD can then be encapsulated with a colloid 11 to form an SMD LED 1, as shown in FIG. 1b.

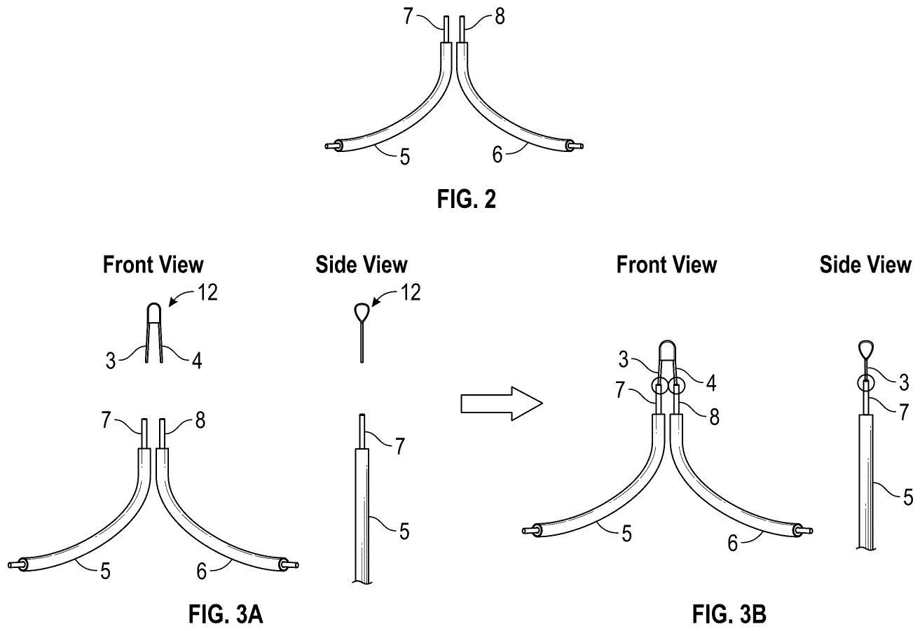

Next, as shown in FIG. 2, two wires 5, 6 are provided. One end of each of the wires 5, 6, have the insulation stripped off to expose the copper wires 7, 8 inside. Additionally, the copper wires 7, 8 can be thinned to facilitate subsequent welding if necessary.

As shown in FIGS. 3a and 3b, the SMD 12 of FIG. 1b can be connected to the exposed ends 7, 8 of wires 5, 6 by welding or any other suitable means such as metal terminals or riveting metal plates. Specifically, each of the metal conductors 3, 4 of the SMD 12 is connected to one of the wires 5, 6, as shown in FIG. 3b.

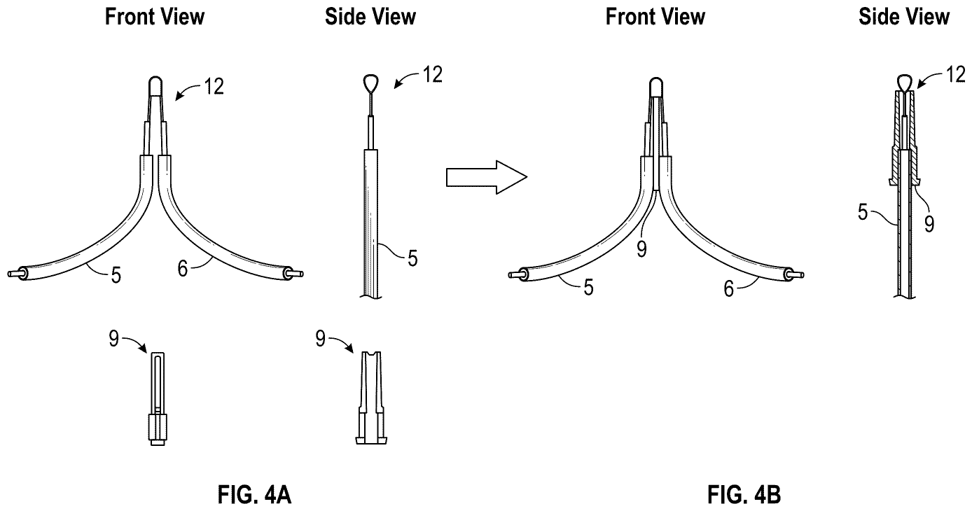

Next, as illustrated in FIGS. 4a and 4b, a rear plug 9 is inserted in a space between the two wires 5, 6, where the wires 5, 6 converge. As illustrated in the side views of FIGS. 4a and 4b, the rear plug 9 can at least partially encapsulate the ends of the wires 5, 6, connected to the SMD LED 12.

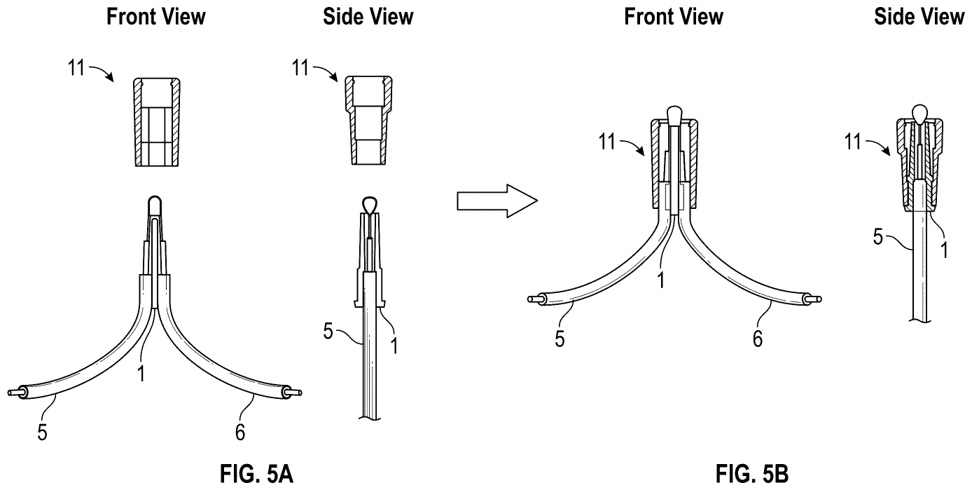

At this stage, there are two different ways to complete the SMD LED assembly. In the first embodiment, the partially-finished assembly of FIG. 4b can be inserted into a lamp holder 11, as illustrated in FIGS. 5a and 5b. A snap joint 1 can optionally be used for stabilizing the assembly within the lamp holder 11. For example, as illustrated in FIG. 5b, the snap joint 1, once inserted into the lamp holder 11, can prevent the wires 5, 6 from moving in some or all directions.

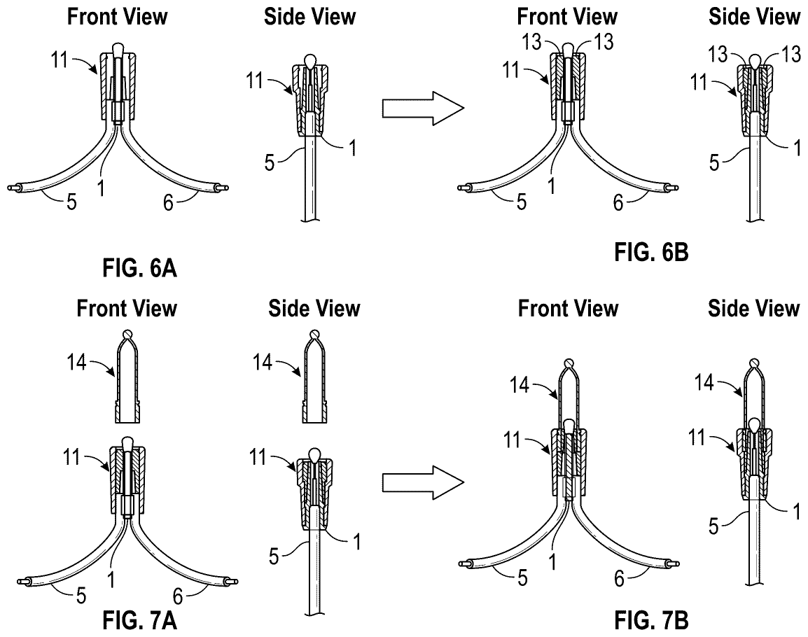

The next step in the first embodiment is illustrated in FIGS. 6a and 6b. In this step, waterproof glue 13 can fill the space inside the lamp holder 11. Referring to FIGS. 7a and 7b, after filling the waterproof glue, but before the glue 13 dries, ornament 14 is placed and secured on the lamp holder 11. Here, the bottom portion of the ornament 14 can fit securely within the lamp holder 11. Ornament 14 can be of different shapes and materials (plastic, glass, etc.). If waterproof glue is not needed, ornament 14 can be added to the assembly after the step shown in FIGS. 5a and 5b is completed, skipping the step of FIGS. 6a and 6b. FIG. 7b illustrates the final assembly of an SMD LED 30.

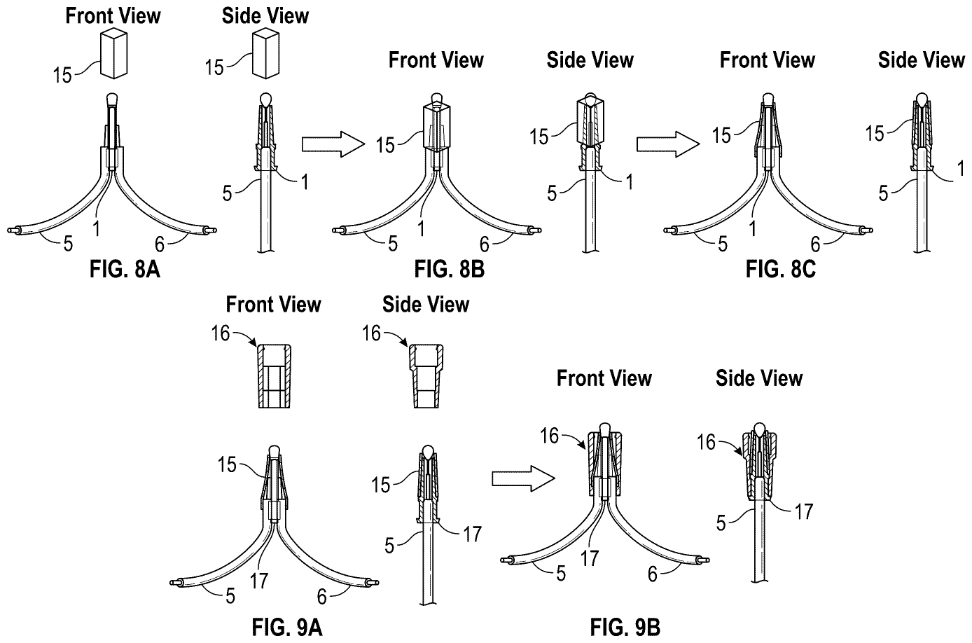

In a second embodiment, after the step of FIGS. 4a and 4b is completed, a heat shrink tubing 15 can be placed over the partially-finished assembly of FIG. 4b (see FIGS. 8a and 8b). The heat shrink tubing can shrink, when heated, to wrap the partially-finished assembly, as shown in FIG. 8c.

Continuing the process of the second embodiment, as illustrated in FIGS. 9a and 9b, the partially-finished assembly of FIG. 8c can be inserted into one end (e.g., tail end) of a lamp holder 16 and secured by snap joint 17 to prevent the partially-finished assembly from moving in one or more directions.

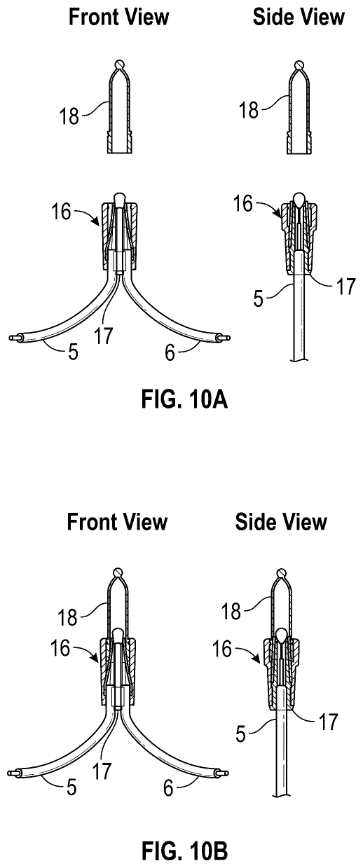

Next, ornament 18 can be added to the partially-finished assembly shown in FIG. 9b. As shown in FIG. 10b, the bottom of the ornament 18 can be inserted and secured between the lamp holder 16 and the heat shrink tubing wrapped SMD LED 1. FIG. 10b shows the final assembly of the SMD LED 32.

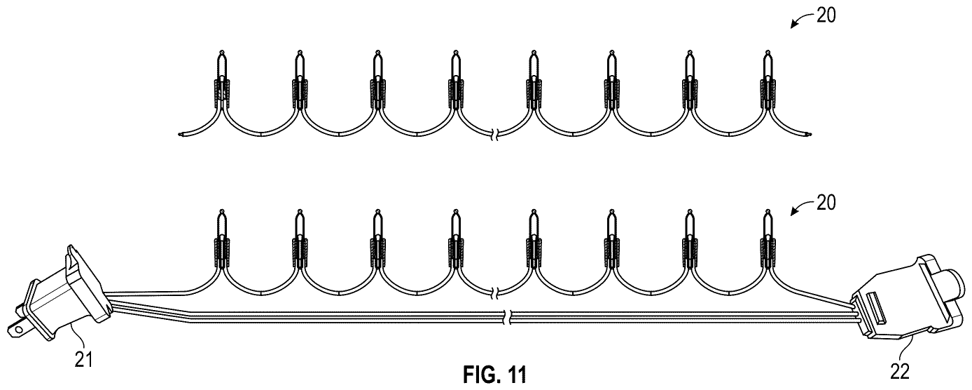

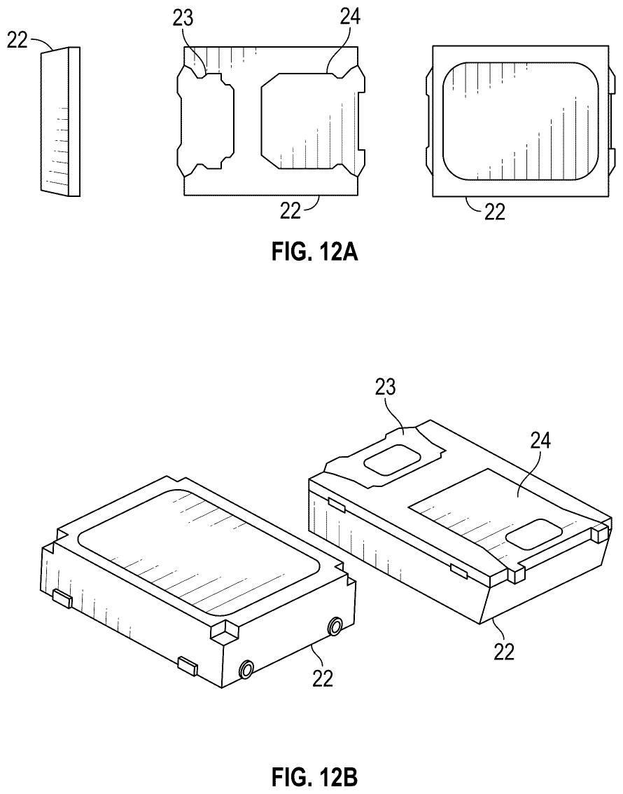

A complete light string 20 can be made by connecting in series multiple SMD LED assemblies such as the ones shown in FIGS. 7b and/or 10b made according to the first and second embodiments, respectively. Front and rear plugs 21, 22, can be added to the light string 20, as illustrated in FIG. 11.

The SMD LED used in the embodiments described above can be SMD LEDs of the various sizes available on the market (e.g., 0603, 0805, 2025 SMD LEDs).

Although embodiments of this disclosure have been fully described with reference to the accompanying drawings, it is to be noted that various changes and modifications will become apparent to those skilled in the art. Such changes and modifications are to be understood as being included within the scope of embodiments of this disclosure as defined by the appended claims.

1. A method of making a Surface Mount Device (SMD) light-emitting diode (LED) plug-in light string, the method comprising:
connecting positive and negative poles of an SMD to a first and a second metal conductors, respectively;
encapsulating at least a top portion of the SMD with a colloid;
connecting the first and second metal conductors to first and second wires, respectively;
inserting a rear plug in a space between the first and second wires to form a partially-finished assembly;
inserting the partially-finished assembly into a lamp holder; and
placing an ornament on the lamp holder;
waterproofing the partially-finished assembly by filling the lamp holder with waterproof glue before the ornament is placed on the lamp holder.

2. The method of claim 1, wherein the positive pole of the SMD is connected to an end of the first metal conductor; and wherein the negative pole of the SMD is connected to an end of the second metal conductor.

3. The method of claim 1, wherein the positive and negative poles of an SMD are connected, respectively, to the first and a second metal conductors by welding.

4. The method of claim 1, wherein the first and second metal conductors are connected to the first and second wires, respectively, by welding.

5. The method of claim 1, wherein the first and second metal conductors are connected to the first and second wires, respectively, by metal terminals.

6. The method of claim 1, wherein the first and second metal conductors are connected to the first and second wires, respectively, by riveting metal plates.

7. The method of claim 1, further comprising: using a snap joint for stabilizing the partially-finished assembly within the lamp holder.

8. and 9. (canceled)

10. The method of claim 1 wherein the ornament is placed on the lamp holder before the waterproof glue dries.

11.-13. (canceled)

14. A light assembly of a string light comprising:
a Surface Mount Device (SMD) having positive and negative poles connected to a first and a second metal conductors, respectively;
a colloid encapsulating at least a top portion of the SMD;
first and second wires each having an exposed end connected to the first and second metal conductors, respectively;
a rear plug inserted in a space between the first and second wires to form a partially-finished assembly;
a lamp holder holding the partially-finished assembly, the lamp holder filed with waterproof glue; and
an ornament secured on the lamp holder.

15. (canceled)
